(19) United States
(12) Patent Application Publication
(10) Pub. No.: US 2003/0017424 A1
(43) Pub. Date: Jan. 23, 2003

(54) Method and apparatus for fabricating complex grating structures

(76) Inventors: Miri Park, New Providence, NJ (US); John Rogers, New Providence, NJ (US)

Correspondence Address: CHRISTIE, PARKER & HALE, LLP, 350 WEST COLORADO BOULEVARD, SUITE 500, PASADENA, CA, 91105, US

(21) Appl. No.: 09/909,358

(22) Filed: Jul. 18, 2001

(51) Int. Cl. G03F 7/00

(52) U.S. Cl. 430/322; 430/5; 430/323; 430/330; 101/3.1

(57) ABSTRACT

An imprint lithography method provides a negative image of a pattern formed in a fixed medium on a mechanically flexible imprint master. A substrate includes a deformable material formed over the substrate surface to be patterned. The fixed medium of the imprint master contacts with the substrate to cause the deformable material to deform and contour to the negative image of the pattern of the fixed medium. The imprint master is decoupled from the substrate after the pattern formed in the deformable material is solidified. With the solidified pattern formed on the substrate, the substrate is then patterned by etching or other means.

### FIELD OF THE INVENTION

The present invention relates most generally to semiconductor lasers. More particularly, the present invention provides a method and apparatus for forming grating structures used in conjunction with semiconductor lasers and other structures.

### BACKGROUND OF THE INVENTION

Grating structures are used in conjunction with distributed feedback (DFB) lasers, DBR (distributed Bragg reflector) structures and other mirror and laser structures formed in the semiconductor and optoelectronics industries. More particularly, grating structures are used to form portions of the mirror and laser structures. A grating structure includes a grating period consisting of a repeating sequence of materials having different refractive indices. A DFB laser, for example, may use the grating structure, also referred to as a grating reflector to tune the laser by adjusting the wavelength of the laser light. A standard DFB laser may include grating periods equivalent to approximately one-half of the wavelength of the light being propagated. By changing or interrupting the grating period, the wavelength of the propagated light may be changed.

It is therefore critical to accurately produce grating structures having the desired grating period or periods. Grating structures are commonly formed on substrates using e-beam or holographic methods to produce an alternating series of adjacent lines which may include lateral dimensions as small as 10 nanometers. E-beam technologies are very expensive and time-consuming. Holographic techniques are rather difficult to control, especially when producing arrays of grating structures which include multiple grating periods.

The present invention is therefore directed to providing an improved method and apparatus for reliably and accurately forming patterns such as grating structures on semiconductor substrates.

### SUMMARY OF THE INVENTION

The present invention provides a method and apparatus for repeatably and accurately producing a pattern in a substrate, such as a grating pattern. The method includes first forming a negative image of the desired pattern in a fixed medium. The fixed medium is formed on an imprint master which may be rigid or mechanically flexible. The imprint master is reusable. After the negative image of the pattern is formed, the imprint master is pressed against a substrate coated with a deformable viscous or liquid material. The deformable material deforms and contours to the negative image formed in the fixed medium, producing the desired pattern on the substrate. The deformable material is then solidified to form a fixed pattern. The pattern may be fixed by curing, for example, by thermal treatment or UV radiation or other appropriate curing means. The solidified fixed pattern formed in the deformable material on the substrate surface is then transferred into the substrate by etching or other means. The top surface of the substrate may include a layer or layers of different materials which may be patterned by the etching process.

It is to be understood that both the foregoing general description and the following detailed descriptions are exemplary but not restrictive of the invention.

### BRIEF DESCRIPTION OF THE DRAWING

The invention is best understood from the following detailed description when read in conjunction with the accompanying drawing. It is emphasized that, according to common practice, the various features of the drawing are not to scale. On the contrary, the dimensions of the various features and the relative dimensions and locations of the features are arbitrarily expanded or reduced for clarity. Each of the figures is a cross-sectional view.

FIG. 1 shows an exemplary negative pattern formed in an exemplary imprint master;

FIG. 2 shows a molding layer formed over grating layers formed on the substrate;

FIG. 3 shows the exemplary imprint master of FIG. 1 positioned over the substrate of FIG. 2;

FIG. 4 shows an exemplary flexible imprint master positioned over the substrate of FIG. 2;

FIG. 5 shows another exemplary flexible imprint master positioned over the substrate of FIG. 2; FIG. 6 shows the imprint master in contact with the substrate being patterned;

FIG. 7 shows the patterned substrate;

FIG. 8 shows the patterned and etched substrate;

FIG. 9 shows an exemplary embodiment of the imprint master/substrate arrangement including additional relief features; and

FIG. 10 shows another exemplary embodiment of the imprint master/substrate arrangement including additional relief features.

### DETAILED DESCRIPTION OF THE INVENTION

The present invention provides a manufacturable method and apparatus for imprinting lithography. The method may be used to fabricate structures having feature sizes of 100 nm and less, for example, complex grating patterns, grating arrays and devices with locally controlled grating periods. Features having lateral dimensions on the order of 10 nm, may be produced. The present invention finds application in DFB laser arrays, wide band detectors with grating array filters for wavelength selection, DBR laser arrays, and any of various other semiconductor or optoelectronic devices.

FIG. 1 is a cross-sectional view showing an exemplary embodiment of imprint master 1. Imprint master 1 includes pattern 9 formed within fixed medium 3.

Pattern 9 includes raised portions 7 and depressed portions 5. Fixed medium 3 may be formed of hard materials, such as silicon and other semiconductor materials, cross-linked polymers, plastics, and other materials. According to an exemplary embodiment, imprint master 1 may be formed entirely of the materials which form fixed medium 3, and in another exemplary embodiment as illustrated in FIG. 1, imprint master 1 may be a composite member including fixed medium 3 as a top portion and also including bulk portion 2 formed of another material. Bulk portion 2 of imprint master 1 may be formed of a material such as silicon, cross-linked polymers, plastics and other materials, and may be generally rigid according to an exemplary embodiment. According to another exemplary embodiment, bulk portion 2 of imprint master 1 may be formed of a mechanically flexible material, such as PDMS (Polydimethylsiloxane). According to yet another exemplary embodiment, imprint master 1 may include fixed medium 3 formed of a mechanically flexible material such as PDMS and bulk portion 2 may be formed of a harder material, such as silicon or glass which is formed thin enough to be somewhat bendable. According to yet another exemplary embodiment, each of bulk portion 2 and fixed medium 3 may be formed of PDMS.

Pattern 9 may be formed by e-beam, optical or other lithography methods, followed by an etching process, such as RIE (Reactive Ion Etching). Pattern 9 may also be formed by plastic or polymer molding techniques. Each of the foregoing embodiments are exemplary and other patterning methods may alternatively be used. Pattern 9 includes raised portions 7 and recessed portions 5. According to the exemplary embodiment in which imprint master 1 is a composite member. Including bulk portion 2 and fixed medium 3, pattern 9 may be formed entirely within fixed medium 3 as shown in FIG. 1, or surface 6 may represent the top of bulk portion 2 such that only raised portions 7 are formed of fixed medium 3. Pattern 9, so formed, is designated a negative image of the desired pattern, and it will be shown in subsequent figures that the pattern formed in the substrate is the negative or opposite of pattern 9 formed in fixed medium 3 of imprint master 1. Stated alternatively, raised portions 7 of pattern 9 of imprint master 1 will produce etched or recessed sections in the patterned substrate. Conversely, recessed portions 5 of pattern 9 of imprint master will form unetched or raised portions of the substrate after patterning such as by etching. Pattern 9 may be a grating pattern or any of various other patterns and may include critical dimensions (feature sizes and spacings between features) less than 100 nm and as low as 10 nm. Raised portions 7 may have substantially orthogonal edges such as edge 10 or they may include rounded edges such as rounded edges 12. Rounded edges 12 offer the advantage of reduced stress created in the pattern later formed on a deformable material. Such stress can result in cracking. For simplicity, raised features 7 will be shown with orthogonal edges in subsequent figures.

Additionally, in subsequent figures, imprint master 1 will be shown to be formed entirely of the same material as fixed medium 3, and therefore bulk portion 2 will not be shown.

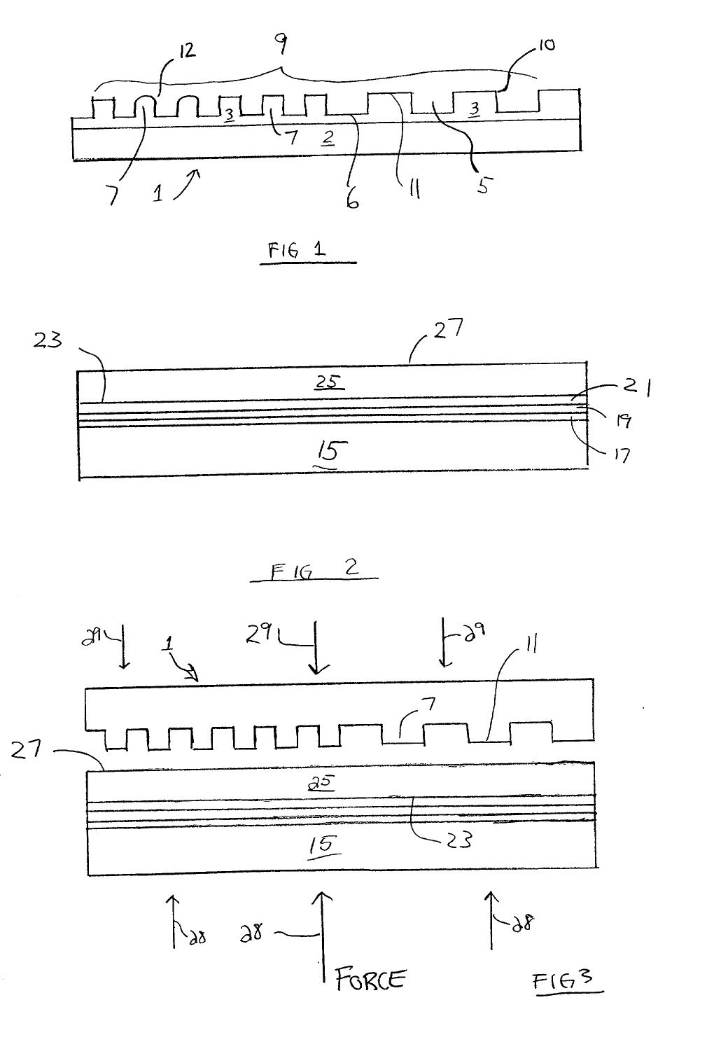

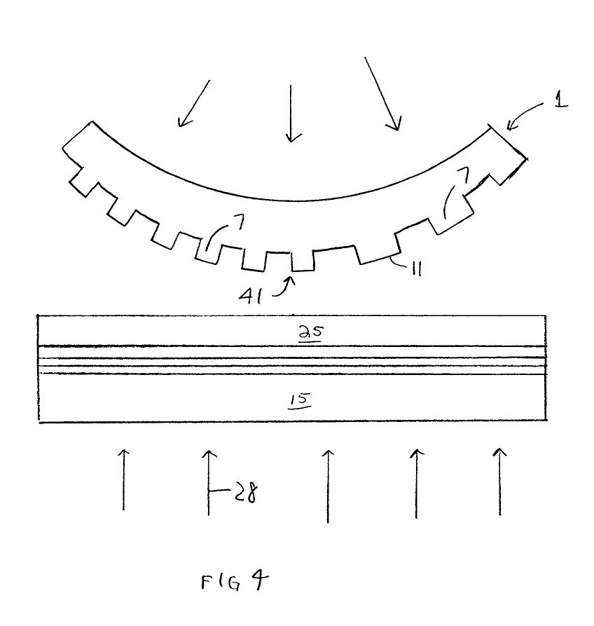

FIG. 2 shows substrate 15 with various layers formed upon it. Substrate 15 may be a silicon, gallium arsenide (GaAs) or indium phosphide (InP) substrate or other suitable substrate materials used in the semiconductor and optoelectronics manufacturing industries. According to other exemplary embodiments, substrate 15 may be a mechanically flexible member. According to the exemplary embodiment shown in FIG. 2, three layers are formed over substrate 15. According to an exemplary embodiment, each of layers 17, 19, and 21, which form the composite structure over substrate 15, may be a film formed by epitaxial methods, such as MBE (Molecular Beam Epitaxy). Other formation methods, such as various plasma deposition techniques, may be used in other exemplary embodiments. According to the exemplary embodiment shown in FIG. 2, lower layer 17 may represent an InP layer; central layer 19 may represent either an InGaAsP layer or a ternary InGaAs layer; upper layer 21 may represent another InP layer; and, substrate 15 may be formed of InP. This is intended to be exemplary only, and the composite film structure may include more or fewer layers than the three shown in FIG. 2. Furthermore, the layers which together form the composite structure, may be formed of various other suitable materials, and according to various other formation methods. In a preferred embodiment, the composite structure may be subsequently patterned according to the present invention to form a grating pattern. Various other patterns may be formed alternatively. According to another exemplary embodiment, substrate 15 may not include any layers formed thereon and the substrate itself may be etched and therefore patterned.

Molding layer 25 is formed over the top surface of the substrate which is top surface 23 of film 21 in the exemplary embodiment. Molding layer 25 is a deformable, viscous material which deforms or flows when contacted by imprint master 1. According to an exemplary embodiment, molding layer 25 may be a liquid. According to an alternative embodiment, molding layer 25 may not deform until heated above a critical temperature such as its glass transition temperature-T_{g}. Molding layer 25 is formed over top surface 23 of substrate 15 according to conventional methods, such as by spin-coating or other coating methods. Other methods for forming molding layer 25 over substrate 15 may also be used. According to an exemplary embodiment, molding layer 25 may be a photoresist material, such as commercially available G-line or i-line photoresists. Other readily deformable, viscous polymer or liquid layers may be used alternatively. Molding film 25 is chosen for compatibility with the substrate and imprint master materials as well as the subsequent processes to be performed on the substrate. According to the embodiment in which heat is applied to urge the deformation of the molding layer, molding layer 25 is chosen to be deformable at a glass transition or other reflow temperature compatible with the materials of which imprint master 1 and fixed medium 3 are formed. The materials are chosen to assure that when molding layer 25 is deformed by heating to its glass transition temperature while being pressed against pattern 9 formed in fixed medium 3 of imprint master 1, for example, pattern 9 does not become distorted. Molding layer 25 is chosen to be easily released from imprint master 1 after patterning. Molding layer 25 is also chosen in conjunction with the etching process which will subsequently be used to etch the substrate or the films formed on the substrate so as to produce a selective etch process and one in which molding layer 25 is not substantially attacked during the etching process used to etch the layers or substrate 15. Furthermore, molding layer 25 is chosen to be chemically unreactive towards fixed medium 3 and imprint master 1, and easily removed after the etching process.

Now turning to FIG. 3, imprint master 1 is inverted so that pattern 9 faces top surface 27 of molding layer 25. Imprint master 1 includes upper or leading surface 11, which represents the upper surface of raised features 7 of imprint master 1. Before force is applied along opposed directions 28 and 29, the facing surface of the imprint master and/or top surface 27 of molding layer 25, may be chemically treated or coated with a release agent. The chemical treatment or release agent is chosen in conjunction with molding layer 25 to ensure that after imprint master 1 is pressed against substrate to form a pattern in molding layer 25, imprint master 1 can be easily removed from molding layer 25 without distorting the pattern formed in molding layer 25. According to an exemplary embodiment, a short-chain thiol, such as alkyl thiol, may be used as a release agent. According to other exemplary embodiments, various hydrophobic layers such as fluorinated silane, and other suitable release agents, may be used alternatively.

To form a pattern within molding layer 25, pattern 9 formed in imprint master 1 is contacted with molding layer 25 after the opposed leading surfaces are positioned substantially parallel to one another and imprint master 1 and substrate 15 are aligned to each other. At least a component of force is supplied along either or both of opposed directions 28 and 29. A machine press or other suitable apparatus may be used to uniformly press the components against each other. The uniformity of the force applied along opposed directions 28 and 29 at various lateral locations of the components and which is used to uniformly force the components together, may be carefully controlled by various suitable means. Molding layer 25 is chosen such that, even at room temperature, extensive force is not required. The precise magnitude of force will vary according to choice of fixed medium 3 of imprint master 1. In the case in which molding layer 25 is a liquid, only minimal force will be required to simply bring imprint master 1 into contact with molding material 25, in order to create a pattern in molding layer 25.

According to the exemplary embodiment in which fixed medium 3 and imprint master 1 are formed of a bendable or mechanically flexible material, such as PDMS, a roller or other mechanical device may be passed over the top surface to ensure uniform contact between leading surfaces 11 of imprint master 1 and substrate 15. Mechanically flexible imprint master 1 will be generally flat and may be bent in order to contact a first portion of molding layer 25, then allowed or urged back into its original flat position to uniformly contact the entirety of molding layer 25. Such a technique prevents air bubbles from being trapped between imprint master and substrate 15. Such air bubbles can distort the pattern being formed.

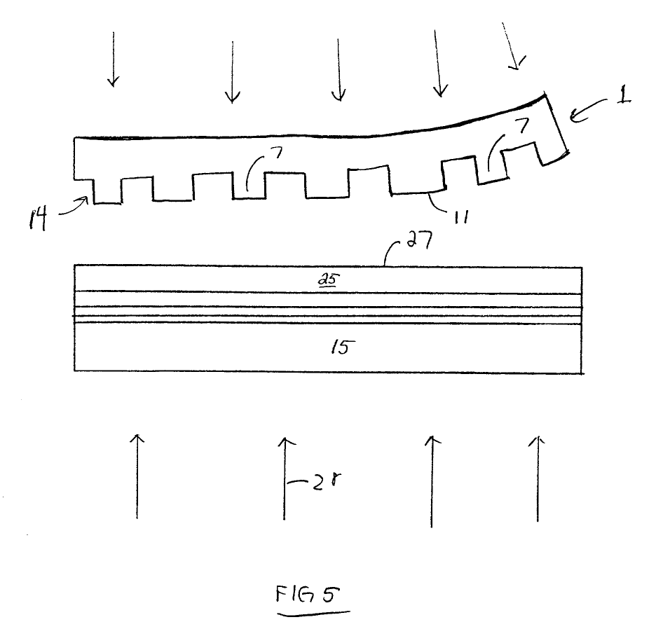

According to one exemplary embodiment, originally-flat imprint master 1 may be bent or bowed slightly so that central portion 41 of imprint master 1 first contacts molding layer 25 formed over substrate 15. This is shown in FIG. 4. Peripheral portions of imprint master 1 are then allowed or urged to contact molding layer 25 of substrate 15 to ensure that bubbles or other anomalies do not form between imprint master 1 and molding layer 25 and thereby distort the pattern. Imprint master 1 is thereby restored to its original flat configuration. According to an exemplary embodiment, imprint master 1 will be formed of a mechanically flexible, yet resilient material which resists bending and returns to its originally flat configuration due to its own resiliency. Conventional mechanical methods may be used to slightly bow imprint master 1, then uniformly press imprint master 1 over substrate 15. According to this exemplary embodiment, each of imprint master 1 and fixed medium 3 may be formed of PDMS.

According to another exemplary embodiment in which imprint master 1 is formed of a mechanically flexible material as shown in FIG. 5, originally-flat imprint master may be bent slightly and brought into contact with substrate 15 such that an edge portion such as edge portion 14 of imprint master 1 first contacts top surface 27 of molding layer 25. Imprint master 1 is then bent or allowed or urged to be restored to its original flat shape in order to uniformly contact the entirety of molding layer 25. A roller may be used, for example. According to either of the embodiments shown in FIGS. 3,4 and 5, after imprint master 1 is initially brought into contact with molding layer 25 of substrate 15, it will be essentially flat over substrate 15 as will be shown in FIG. 6.

According to an alternative embodiment, substrate 15 may be heated to promote viscosity of deformable molding layer 25. Heat may be applied to the substrate prior to pressing the components against each other, heat may be applied during the process of pressing the components against one another, or heat may be applied at both of the aforementioned stages of the process. Heat may be applied by various suitable and conventional means. For example, substrate 25 may be seated on a hotplate or the machine press or other apparatus which may house the units being contacted against each other, may include a heated chamber, such as a chamber heated by convection. The heat applied is sufficient to raise the temperature of molding layer 25 above a critical value such as its glass transition temperature, T_{g}. This ensures that molding layer 25 is in a deformable or viscous state when it is brought into contact with pattern of imprint master 1.

FIG. 6 shows the two components pressed against each other. Leading surface 11 of imprint master 1 preferably contacts top surface 23 of upper film 21 formed on substrate 15. Molding layer 25, which is in a deformable or viscous state, conforms to the features of pattern 9 formed in imprint master 1. If a “pattern” is considered to be raised features off of a surface, it can be seen that the desired pattern formed within molding layer 25 over substrate 15 is the negative image of pattern 9 formed in imprint master 1. Width 26 of features formed in molding layer 25 and spacing 38 formed between the features of molding layer 25 may be on the order of 100 nm or less. These features and spaces will be translated into features and spaces on the substrate. According to an exemplary embodiment, dimensions such as width and spacing 38 may be as low as 10 nm.

The pattern formed in molding layer 25 is then fixed. Various solidification techniques may be used to fix molding layer 25, depending on the material of which molding layer 25 is formed. Curing, for example, by thermal treatment or UV-radiation may be used in various exemplary embodiments in which molding layer 25 is a polymeric material. Other appropriate curing means may be used alternatively. According to the exemplary embodiment in which heating was used to promote the viscosity of molding layer 25, a cooling process may be used to solidify molding layer 25.

After molding layer 25 is solidified, imprint master 1 is removed from the arrangement. Conventional cooling methods may be used if heat was applied during the molding or curing process. According to the exemplary embodiments in which either or both of the imprint master and the substrate are formed of a mechanically flexible material, the coupled components (imprint master 1 and substrate 15) may be decoupled by peeling or slightly bending the mechanically flexible component or components, thereby separating them from one another. Various other conventional mechanical means may be used to decouple the components without distorting the features of the pattern formed on the substrate. Imprint master 1 may then be cleaned using conventional methods, then reused.

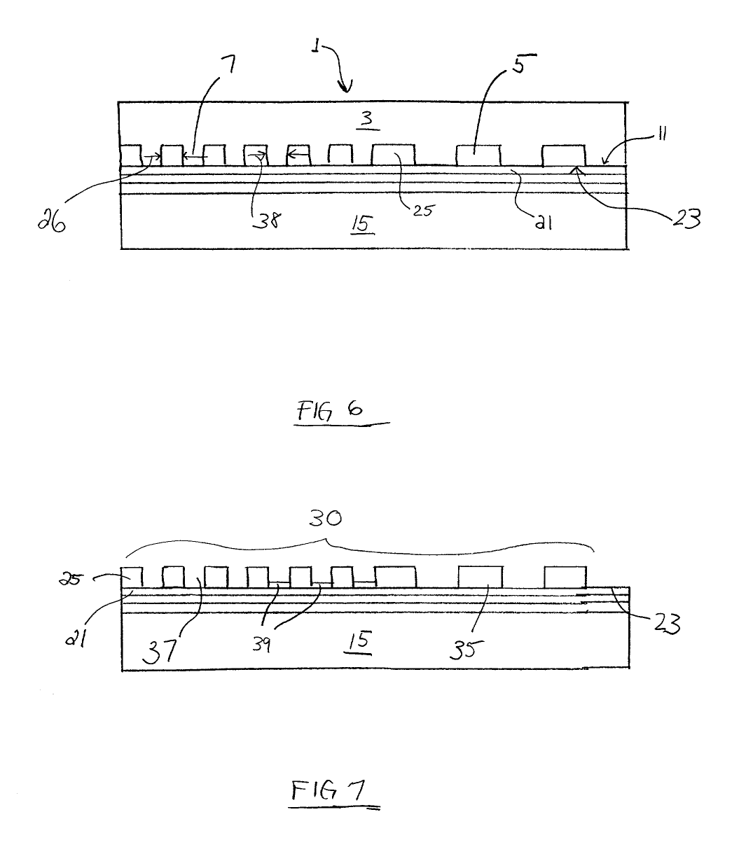

FIG. 7 shows substrate 15 after imprint master 1 has been decoupled from the arrangement. Desired pattern 30 formed of molding layer 25 over surface 23 of substrate 15, includes spaces or void areas 37 and features 35. Features 35 correspond to recessed portions 5 of pattern 9 formed in imprint master 1. Conversely, spaces or void areas 37 correspond to features 7 formed in the negative image of the pattern, i.e. pattern 9 of imprint master 1. It should again be emphasized that desired pattern 30 is exemplary only and that any of various patterns including single or multiple grating structures or other features may be formed. At this point, pattern 9 may optionally be solidified by thermal, UV-radiation or other suitable curing means.

Void areas 37 of desired pattern 30, may include a small amount of molding layer 25 residual on surface 23. In a preferred embodiment, surface 23 will be void of molding layer 25 in void areas 37. As such, a relatively thin section of molding layer 25 is shown as thin residue layer 39 in some of void areas 37 shown in FIG. 7. Features 35 therefore represent a relatively thick portion of molding layer 25 and void areas 37 may include a thin residue layer 39 of molding layer 25 over substrate 15. Thin residue layer 39 may alternatively be referred to as a scumming layer. The illustration of FIG. 7 is intended to be exemplary only and all of void areas 37 may be free of molding layer 25 according to other exemplary embodiments; conversely, each of void areas 37 may include thin residue layer 39 of molding layer 25, according to other exemplary embodiments. After desired pattern 30 is formed, the substrate is ready to be etched.

According to an exemplary embodiment, prior to the etching of the substrate, desired pattern 30 consists of relatively thick portions 35 of molding layer 25 and relatively thin residue portions 39 of molding layer 25. The relatively thin residue portions 39 of molding layer 25 formed within void regions 37, may be removed using reactive ion etching, or other conventional and suitable “de-Scum” methods. According to an exemplary embodiment, this removal step may be performed in-situ with the etching process subsequently used to etch substrate 15.

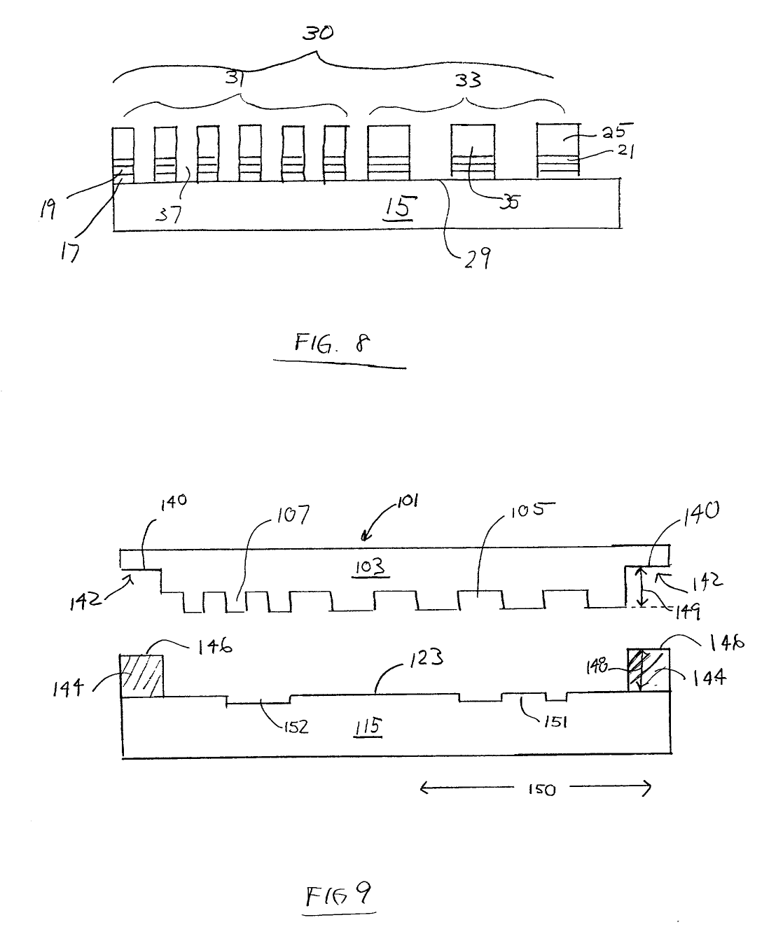

Now turning to FIG. 8, substrate 15 is shown after the substrate has been etched using desired pattern 30 formed in molding layer 25, as a masking medium. FIG. 8 shows that the sections of layers 17,19 and 21 which were not protected by thick portions 35 of molding material 25, have been removed by etching. The etching process is carried out after any residual thickness of the molding film has been removed from void areas 37. Various suitable etching processes may be used. The etching process is chosen in conjunction with the films to be etched. According to an exemplary embodiment, RIE etching may be used. A selective etching process is chosen so that relatively thick portions 35 of molding film 25 will be substantially intact during and after the etching process. Desired pattern 30, which has been translated from the molding film into the substrate, may be any of various patterns. It may include a single grating period as grating period 31. It may include a single grating period having a larger pitch such as grating period 33. Pattern 30 may also include multiple grating periods such as each of grating period 31 and grating period 33 shown in FIG. 8. It should be emphasized at this point that the structure shown in FIG. 8 is exemplary only and that any of various other patterns may be formed in the substrate according to this procedure. This procedure is not intended to be limited to forming grating patterns.

After the structure illustrated in FIG. 8 is achieved by etching, conventional methods may be used to remove molding film 25 from over the substrate. Various subsequent processing operations may then be carried out upon the substrate which has been etched to include desired pattern 30. For example, in the exemplary embodiment in which grating period or periods are formed, and in which lower film 17 and upper film 21 are each formed of InP, and according to the case in which central layer 19 is formed of one of InGaAs or InGaAsP, void areas 37 between the etched features may be subsequently filled in with InP according to the embodiment in which a grating period is formed either below or above an active layer along which light will be propagated. The above recited films and structures are intended to be exemplary only.

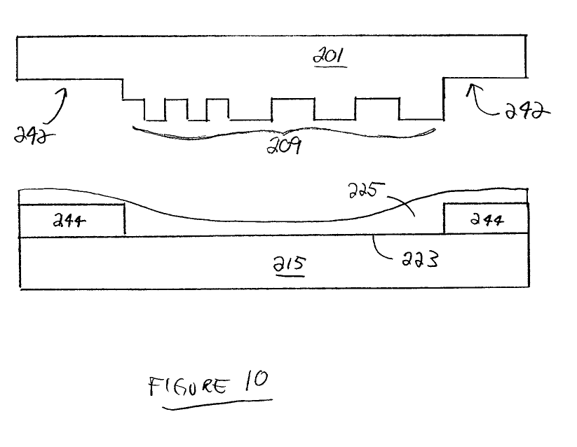

According to another aspect of this invention and as in the exemplary embodiment shown in FIG. 9, each of substrate 115 and imprint master 101 may be formed to include corresponding alignment structures. In an exemplary embodiment, the alignment structures may include raised portions, such as raised portions 144 formed over surface 123 of substrate 115. Corresponding recessed portions 142 are formed in imprint master 101, such that raised portions 144 mate with corresponding recessed portions 142 and top surfaces 146 of raised portions 144 and recessed surfaces 140 of recessed portions 142 of imprint master 101, are in contact with each other when the components are in contact with each other. Recessed portions 142 are recessed to an extent greater than the base portions 105 of the portion formed in imprint master 101. According to another embodiment, the disposition of the corresponding raised and recessed portions may be reversed such that recessed portions 142 are formed on substrate 115. The components are pressed against each other after a molding film (not shown) is formed over substrate surface 123 as described in conjunction with FIGS. 1-8 and after the corresponding alignment features are aligned to one another. According to an exemplary embodiment, the corresponding alignment structures 142 and 144 may be disposed peripherally on the substrate.

The corresponding alignment structures are aligned to one another before imprint master 101 and substrate 115 are brought into contact with one another. The corresponding alignment structures are formed and positioned to ensure that, when engaged, the patterns are aligned with respect to lateral 150 and rotational directions, and thickness 148 and depth 149 are chosen to ensure that imprint master 101 is disposed in the desired vertical location with respect to substrate 115 when the components are joined. This is especially critical when a pattern has already been formed within substrate 115. Such a pattern is shown to include raised portions 151 and recessed portions 152. Height 148 of raised portions 144 may be chosen such that, when a molding layer (not shown) is formed over substrate 123 such as by coating, for example, it will not extend above top surfaces 146. According to the embodiment in which the substrate has previously had topographical features formed upon it by various patterning methods, the height of raised features 107 of imprint master 101 is chosen to ensure that, after the deformable molding material (not shown) is molded into a pattern, the height of the molding material formed after patterning is sufficient to enable an etching or similar process to be carried out on various regions of the already-patterned substrate in order to further pattern the substrate.

According to yet another aspect of this invention, such as illustrated in FIG. 10, imprint master 201 may include relief features formed to mate with corresponding physical device features formed on substrate 215. For example, if raised features such as exemplary discrete device features 244 are formed on portions of substrate 215 not being presently patterned using imprint master 201, imprint master 201 may include recessed regions 242 corresponding to the locations on substrate 215 where device feature 244 is disposed. Device feature 244 may be a segment of an oxide layer, according to an exemplary embodiment. Molding layer 225 may be formed over surface 223 by a procedure and to a thickness such that it covers the raised features such as device feature 244 as shown in FIG. 10. Alternatively, molding layer 225 may be formed so as not to extend over device feature 244. According to either exemplary embodiment, the patterning process is then carried out as described in conjunction with FIGS. 1-8. It can be seen that recessed regions 242 are recessed into imprint master 201 to a greater extent than pattern 209 formed on imprint master 201. According to another exemplary embodiment, the extent of recession of recessed regions 242 may be less than or equal to the depth of pattern 209 formed on imprint master 201.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. For example, the substrate itself may be etched into a pattern according to the method disclosed, and various other films and combinations thereof may be formed over the substrate and then etched according to the process disclosed above. Furthermore, the pattern formed according to this method may represent a grating period, several grating periods, an array of grating periods or any other pattern required to be formed over a substrate in the semiconductor or optoelectronics manufacturing industry. The pattern may include features transverse to the cross-sectional view of the pattern which are shown in the figures.

Moreover, all statements herein reciting principles, aspects, and embodiments of the invention, as well as specific examples thereof, are intended to encompass both structural and functional equivalents thereof. Additionally, it is intended that such equivalents include both currently known equivalents, such as equivalents developed in the future, i.e., any elements developed that perform the same function, regardless of structure. The scope of the present invention, therefore, is not intended to be limited to the exemplary embodiments shown and described herein. Rather, the scope and spirit of the present invention is embodied by the appended claims.

What is claimed is:

1. A method for patterning a substrate comprising:
providing a substrate;
providing a negative image of a pattern in a fixed medium on a mechanically flexible imprint master;
forming a deformable material over a surface of the substrate;
contacting the deformable material with the negative image of the pattern thereby urging the deformable material to deform into the pattern over the surface of the substrate;
removing the imprint master from the substrate; and
transferring the pattern into the substrate.

2. The method as in claim 1, in which the substrate is formed of a mechanically flexible material and the step of removing includes bending the substrate to remove the imprint master from the substrate.

3. The method as in claim 1, wherein the step of providing the negative image of the pattern comprises forming raised portions and base portions within the fixed medium, the base portions corresponding to the pattern.

4. The method as in claim 3, in which the step of providing the negative image of the pattern includes forming the raised portions to have rounded cross-sectional areas.

5. The method as in claim 1, in which the substrate includes a composite structure of a layer of InP formed over a layer of InGaAsP or InGaAs formed, in turn, over a layer of InP, and the step of patterning the substrate includes forming a pattern within the composite structure.

6. The method as in claim 1, further comprising forming a release agent on the negative image of the pattern prior to the step of contacting.

7. The method as in claim 6, wherein forming a release agent on the negative image of the pattern comprises coating the negative image of the pattern with a short chain thiol.

8. The method as in claim 1, wherein the pattern of the deformable material is formed to include relatively thin residual sections of the deformable material and relatively thick sections of the deformable material and further comprising the step of removing the relatively thin residual sections of the deformable material prior to the step of transferring the pattern into the substrate.

9. The method as in claim 1, in which the step of providing the negative image of the pattern includes forming the negative image of the pattern by one of optical or e-beam lithography followed by RIE etching.

10. The method as in claim 1, further comprising the step of heating one of of before and during the step of contacting.

11. The method as in claim 10, wherein the heating comprises heating above a glass transition temperature of the deformable material.

12. The method as in claim 1, wherein the deformable material comprises a liquid.

13. The method as in claim 1, wherein the deformable material comprises one of photoresist and a viscous polymer.

14. The method as in claim 1, in which the pattern includes a grating structure.

15. The method as in claim 1, in which the imprint master includes first physical alignment structures and the substrate includes corresponding second physical alignment structures and wherein the first physical alignment structures are aligned to the corresponding second physical alignment structures prior to the step of contacting, and the first physical alignment structures mate with the corresponding second physical alignment structures during the step of contacting.

16. The method as in claim 15, in which the second physical alignment structures are film segments formed over the substrate and the first physical alignment structures are recessed portions within the imprint master, the film segments being previously formed portions of a semiconductor device formed on the substrate.

17. The method as in claim 15, in which the second physical alignment structures are raised relief features formed on the substrate and the first physical alignment structures are recessed portions which are recessed into the imprint master to an extent greater than the negative image of the pattern formed on the imprint master.

18. The method as in claim 1, wherein the step of transferring the pattern into the substrate comprises etching the substrate using the deformable material as a mask.

19. The method as in claim 1, wherein each of the fixed medium and the imprint master comprises polydimethlysiloxane (PDMS).

20. The method as in claim 1, further comprising the step of curing the pattern of deformable material after the step of contacting, using one of a thermal treatment and UV radiation.

21. The method as in claim 1, further comprising the step of bending the imprint master one of prior to and during the step of contacting.

22. The method as in claim 1, in which the imprint master includes a generally flat original configuration, further comprising the step of bending the imprint master prior to the step of contacting, and in which the step of contacting includes allowing the imprint master to resile to its original flat configuration.

23. The method as in claim 1, in which the step of removing includes bending the imprint master.

24. The method as in claim 1, in which the negative image of the pattern includes at least one lateral dimension being less than 100 nm.

25. A lithographic imprint master formed of a mechanically flexible material and including a pattern formed in a fixed medium thereon, the pattern including device features having dimensions no greater than 100 nm.

26. The lithographic imprint master as in claim 25, wherein the lithographic imprint master is formed of a resilient material.

27. The lithographic imprint master as in claim 25, wherein the lithographic imprint master is formed of polydimethylsiloxane (PDMS).

28. The lithographic imprint master as in claim 25, in which the lithographic imprint master is adapted for contacting a deformable material formed on a surface and deforming said deformable material into the pattern.

29. The lithographic imprint master as in claim 28, further comprising raised alignment features formed on the surface and corresponding recessed alignment features formed on the lithographic imprint master.
